(19) United States
(12) Patent Application Publication
(10) Pub. No.: US 2010/0183420 A1
(43) Pub. Date: Jul. 22, 2010

(54) TRANSFER DEVICE FOR AN OVERHEAD CONVEYING SYSTEM

(76) Inventors: Jakob Blattner, Ermatingen (CH); Rodolfo Federici, Berg (CH)

Correspondence Address: MCGLEW & TUTTLE, PC, P.O. BOX 9227, SCARBOROUGH STATION, SCARBOROUGH, NY, 10510-9227, US

(21) Appl. No.: 12/516,261

(22) PCT Filed: Nov. 27, 2007
(86) PCT No.: PCT/CH07/00592

§ 371 Date: Feb. 4, 2010

(30) Foreign Application Priority Data
Nov. 27, 2006 (CH) 1909/06

(51) Int. Cl. H01L 21/677; H01L 21/687; B65G 57/00

(52) U.S. Cl. 414/788.1; 414/222.01; 414/806

(57) ABSTRACT

Disclosed is a transfer device (5) for substrates used for producing electronic components or displays. Said transfer device (5) is used for delivering substrates to a process station (4) and comprises a first feeding/discharge interface (7) to an overhead conveying system (1) for substrate transport boxes (2) as well as a second feeding/discharge interface (26) to the process station (4). The first interface (7) is located above the second interface (26) relative to a vertical direction. In order to provide such a transfer device (5) with greater flexibility in terms of the order in which the conveyed substrates are delivered to process stations (4) in an interlinked production plant for conveying substrates in transport boxes (2), said transfer device (5) comprises means (24, 25, 27) which allow the substrates to be conveyed from one interface (7) to the other (26) free from transport boxes (2) with the help of a handling mechanism (12) that is arranged within the transfer device (5).

The invention relates to a transfer device for substrates from the field of the manufacture of electronic components or displays, which is provided for the delivery of substrates to a process station, wherein the transfer device has a first feeding/discharge interface to an overhead conveying system for substrate transport boxes and a second feeding/discharge interface to the process station, with the first interface being arranged here above the second interface in relation to a vertical direction. The invention additionally relates to a method according to the introductory clause of Claim 13.

In manufacturing plant which are automated to the greatest possible extent, for electronic components such as for example processors, memory chips, screen panels and suchlike, the substrates which are required for this or which are to be processed are transported to and fro in transport boxes by means of a conveying system between the process stations in which they are processed or intermediately stored. The conveying systems are in many cases constructed as raised conveying systems, so-called Overhead transport Hoist Transport (OHT). For this, the substrates in their transport boxes and together therewith are received by a generic charging device, as described for example in WO 2005006480 A1 or WO 2004023530 A3, and are introduced at the first feeding/discharge interface. Through a substantially vertical transport movement of the transport boxes within the charging- or transfer device, the transport boxes can then be transferred to the second feeding/discharge interface, at which they are delivered from the transfer device to a station in which the substrates are processed or are otherwise required. On the reverse travel, the transport boxes which are empty or are filled with substrates can be brought from the respective station again in an automated manner to the conveying system.

In such transfer devices, their low flexibility with respect to reaction possibilities in the case of altered processing sequences of the substrates can be regarded as a disadvantage.

The invention is therefore based on the problem of making available a possibility for the automated transfer of substrates, which in connection with an interlinked production station for the transporting of substrates in transport boxes makes possible a greater flexibility in the sequence of the supplying of the delivered substrates to process stations.

This problem is solved according to the invention in a transfer device of the type mentioned in the introduction by means by which the substrates are able to be transported by a handling mechanism arranged in the transfer device, free of transport boxes, from one feeding/discharge interface to the other. The invention is therefore based on the idea of removing the substrates from the transport boxes at the latest within the transfer device, so that the substrates within the transfer device can also be handled openly for other purposes than purely carrying in and out at the interfaces, in particular can also be intermediately stored openly in a storage arrangement.

In connection with the present invention, “free of transport boxes” is to be understood to mean that the substrates are removed from a magazine of the respective transport box at the latest directly behind the sluice-like feeding/discharge interface to the overhead conveying system and from here are handled within the transfer device without any component of a transport box. In addition, this includes the fact that at the most components of the transport boxes are introduced for a short time into the housing for the removal of substrates immediately behind the said feeding/discharge interface, in order to be subsequently carried out again through the same feeding/discharge interface. In a transfer device according to the invention, however, no transport boxes are to be stored or carried through.

These steps open up the possibility in particular of bringing the substrates into a sequence and/or orientation within the transfer device with a handling mechanism through a suitable manipulation, as is necessary for the subsequent processing in the connected process station and as possibly occurs only for a short period of time. With a transfer device according to the invention, therefore altered requirements can be responded to very quickly and, above all, flexibly. For this, unlike hitherto, a time-consuming transporting away of the substrates to a remotely arranged station is necessary, in which only a new wafer stack can be prepared. Apart from wafers, the transfer device is also suitable for all other substrates which are required in the field of the manufacture of electronic components or apparatus, in particular also for reticles and screen panels.

The step according to the invention is the prerequisite for equipping a transfer device for connecting to an overhead conveying system for the first time with an intelligence through which more than the hitherto mere movement of the substrates from the upper to the lower interface and vice versa is possible. As a transfer device according to the invention closes the gap between the transfer/receiving position for transport boxes on the overhead conveying system and the feeding/discharge interface of a process station and is to be arranged in this gap, transfer devices according to the invention can be integrated into already existing manufacturing plant without great expenditure. In a surprisingly simple and nevertheless very advantageous manner, the region which was scarcely used hitherto between the transfer/receiving position and the feeding/discharge interface of a process station can be provided with a distinctly greater functionality for the logistical preparation of the substrates or the stacks which are formed with them. This leads in particular to a considerably shortening of the storage times—and hence to a shortening of the throughput times—of the substrates.

It is preferred here if the transfer device according to the invention has an upper feeding/discharge interface which—in vertical direction—is situated as close as possible to the overhead conveying system. Hereby, on the one hand the conveying path between the transfer device and the overhead conveying system becomes as short as possible and the transfer thereby becomes possible with little technical effort. On the other hand, hereby also, despite a small footprint of the transfer device, a large volume becomes possible within the transfer device, which permits various functional units to be held, for example a storage arrangement with a particularly large holding capacity for substrates.

As it is possible with the transfer device according to the invention to make available each substrate already delivered by the overhead conveying system immediately on demand to the respective process station, in particular dwell times of substrates and transport boxes outside their treatment process before the process station can be markedly reduced. As a result, this reduces the manufacturing costs, because for the same quantity of electronic components to be produced, viewed over a particular period of time, fewer substrates and transport boxes than hitherto are in circulation in a factory at the same time. The processing of the individual substrates takes place more quickly than hitherto. In addition, the quicker reaction time to a request to deliver particular substrates, in particular wafers, to the process station, which is possible with the invention also opens up the possibility of working with smaller batch sizes than hitherto and of nevertheless achieving comparable quantities of processed substrates.

In addition, the advantage can be achieved of being able to at least largely dispense with cost-intensive storage arrangements for transport boxes. If, as is provided in a preferred embodiment, within a closable housing of the transfer device the substrates are introduced and also intermediately stored there if required in a storage arrangement, then in a manufacturing station with a distinctly reduced number of transport boxes in circulation at least the same quantity of substrates can be processed or used.

In particular a preferred embodiment of the transfer device can contribute to the achieving of these advantages, which has a storage area in which a storage arrangement is arranged for the intermediate storage of substrates. The storage arrangement can, for example, have a conventional rigid magazine or else a storage arrangement for the highly-compacted storage of substrates, as is described in WO2005006407 and PCT/CH2006/000356. The content of the two documents is included herewith by reference. Such a storage arrangement can contain individual storage elements which are able to be stacked one on another to form a storage stack. In the stack, such storage elements sit one on another with their stack area and preferably have in the interior a region to receive a substrate respectively. The stack area and the receiving area of the individual storage elements can be staggered with respect to each other in vertical stacking direction. With such storage elements, a highly compacted storage of substrates can be achieved and at the same time a storage of the substrates which is not accessible from the exterior without additional manipulation of the stack and is hence protected against mechanical damage or contamination with particles.

In a preferred further development, the transfer device can have an upper feeding/discharge interface, at which transport boxes which have been delivered from an overhead conveying system (Overhead Hoist Transport OHT) are transferred to the transfer device, in order to also open the transport boxes outside a housing of the transfer device. The substrates are then subsequently removed from a magazine of the respective transport box and introduced into the transfer device. Such feeding/discharge interfaces are offered by the applicant in another technical connection under the product name SMIF-Loadport and FOUP-Loadport (for the respective SMIF or FOUP transport boxes). A feeding/discharge interface preferably has a means for opening and closing the respective transport box type. In the region of this first feeding/discharge interface, the transfer device can also be constructed for the transfer of substrates to an internal handling mechanism, in particular to a stack gripper and/or single gripper.

Before the actual feeding/discharge interface, the transfer device can have a movement element or a transport box changer outside its housing, by which a transport box can be transported from a first position, at which an opener for the transport box is situated, to a second position (buffer position) and vice versa. For this, the movement element can for example carry out a straight or else a rotary movement. Such an exchange method for transport boxes makes it possible, within a particular period of time, to handle as large a number of transport boxes as possible, because the first feeding/discharge interface is only occupied by a transport box for as long as is imperatively necessary.

In a further expedient development, the transfer device can have a handling mechanism arranged in its housing, which is preferably movable between the two feeding/discharge interfaces.

Further preferred developments of the invention will be apparent from the claims, the description and the drawings.

The invention is explained in further detail with the aid of example embodiments illustrated purely diagrammatically in the figures, in which are shown:

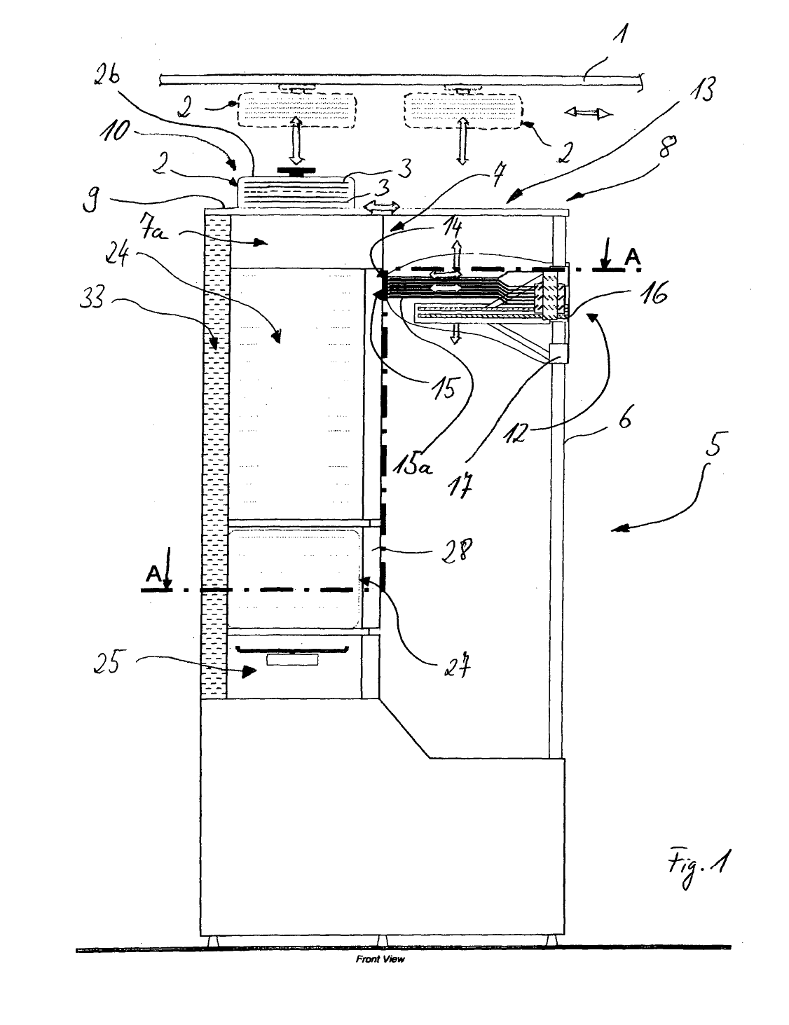

FIG. 1 a side view onto a preferred embodiment of a transfer device according to the invention, which is constructed for a first transport box type

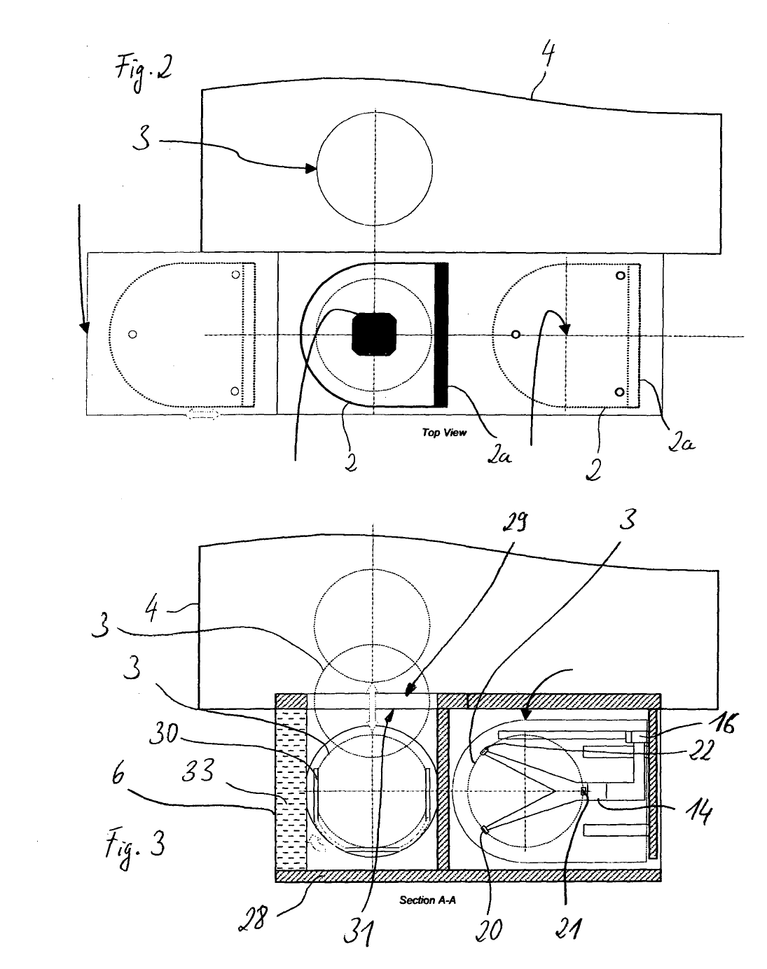

FIG. 2 a top view onto a transfer device as shown in FIG. 1, which is constructed for a second transport box type;

FIG. 3 a sectional illustration along the line A-A through the transfer device of FIG. 1.

In FIGS. 1 to 3 a section of an overhead conveying system 1 is illustrated, as is frequently used in automated manufacturing plant for the manufacture of electronic chips. With such overhead conveying systems in standardized transport boxes 2, such as for example so-called FOUP boxes or SMIF boxes, wafers 3 are transported, from which the electronic components are produced through various processing operations. For this, the wafers 3 must be delivered to the individual process stations 4 (FIG. 3) which are arranged distributed in the manufacturing plant.

In the figures, a transfer device 5 according to the invention is provided for supplying the wafers to a process station 4. In the region of the overhead conveying system 1, the transfer device 5 has on its closable housing 6 a first feeding/discharge interface 7, which is arranged at least approximately at the level at which transport boxes are transported by the overhead conveying system and are delivered to the transfer device 5. In order to bring the individual transport boxes 2 from the overhead conveying system 1 to the first feeding/discharge interface and back, a transport box changer 8 is provided. On a platform 9 of the transport box changer 8, a transport box can be deposited by the overhead conveying system 1 on a first position 10 and secured at the interface 7. It is preferred if the overhead conveying system 1 merely frees the respective transport box for this, and for example the transport box arrives directly to position merely by a disengaging process. Hereby, in particular a lift-free transfer of transport boxes by the overhead conveying system 1 to the transfer device is possible, and vice versa. Depending on the orientation with which the transport boxes 2 are delivered to the transfer device 1, it can be necessary that the changer 8 is also provided with means by which it is capable of re-orientating the respective transport box 2 by a rotary movement. Hereby for example FOUP boxes 2, as are shown in FIG. 2, can be aligned with their closable FOUP door 2a, arranged on the front face of the respective box 2, to the feeding/discharge interface 7.

In the case of a SMIF box 2, with an arrangement known per se, the base part together with the magazine of the box 2 and the wafers stored horizontally therein is introduced into the housing 6 of the transfer device to a charging position 7a directly behind the housing wall. The cap 2b of the SMIF box remains outside. With a handling mechanism 12 arranged on one side of the transfer device 5 in its housing 6 and able to be moved respectively linearly in several spatial directions, the magazine, which is not illustrated in further detail in the figures, can be emptied. The wafers are handled inside the transfer device 1 in a manner which will be further discussed below.

The base of the SMIF transport box 2 can now be taken out from the transfer device 1 again with the emptied magazine, and connected with the cap 2b of the transport box 2. The transport box 2 is hereby arranged again on the first position 10 of the transport box changer 8. Through a displacement movement of the transport box changer 8, the transport box 2 can be transferred to a second position 13 of the changer, in which it either remains for the time being or else is received by the overhead conveying system 1 to be transported off. In the illustration of FIG. 1, two transport boxes 2 are shown with dashed lines, one of which is situated shortly before the transfer to the first position 10, and the other of which is situated directly after reception by the overhead conveying system 1 from the second position 13. The said displacement movement(s) of the transport box changer 8 can either be a linear movement or else a rotary movement of the platform 9.

Inside the housing 6 of the transfer device 5, in its right-hand half in FIG. 1 the handling mechanism 12 is provided for the handling of the wafers which has already been mentioned. In the example embodiment which is shown, the handling mechanism has an upper single gripper (single-wafer gripper) 14 and a stack gripper (batch gripper) 15 arranged therebeneath. The single gripper 14 and the stack gripper 15 are arranged on a shared slide carrier 16 which is movable in Z direction via a conventional linear axis 17 within the housing.

As can be seen in FIG. 1 and in FIG. 3, the single gripper 14 can be constructed in a manner known per se, for example as a two-armed gripper, on which a single wafer 3 is arranged in a three-point bearing 20, 21, 22. The single gripper can be used in particular to assemble new wafer stacks inside the transfer device, and/or to deliver individual wafers to a functional unit of the transfer device and remove them therefrom.

The stack gripper 15 of the example embodiment which is shown is composed of five individual grippers 15a, which are respectively provided to receive only one wafer. The individual grippers 15a of the stack gripper 15 are only movable together in X direction, i.e. in horizontal direction in the illustration of FIG. 1. The grippers of the stack gripper 15 have a distance from each other in vertical direction which corresponds to the distance of the wafers in the transport boxes or in magazines of transport boxes. The grippers 15a of the stack gripper 15 can also be constructed as grippers with a three-point bearing. In the example embodiment, the stack gripper 15 has five grippers 15a, which carry out all the movements exclusively together and hence synchronously. In other embodiments of the invention, the stack gripper 15 can also be provided with a different number of grippers 15a. In addition, provision may also be made that the grippers 15a are able to be actuated independently of each other, for example in order to receive or deposit wafers.

The stack gripper 15 and the single gripper 14 are arranged on the slide carrier 16 so as to be movable relative to each other respectively. These displacement movements are movements which are necessary or useful for a reception of wafers on the respective gripper 14, 15, a releasing of the received wafers in the magazine, a removal from the magazine, a transport movement in Z direction and for a depositing or for a transfer of the wafers. The grippers can therefore be passive grippers, the receiving and depositing movement of which is produced substantially by a displacement movement of the slide carrier 16.

In the illustration of FIG. 1 on the left adjacent to the handling mechanism 12 and its shaft-like vertical displacement area, a storage arrangement 24 is provided for an open intermediate storage of wafers outside transport boxes or magazines of the transport boxes. The storage arrangement 24 can have a storage capacity which is a multiple of the content of usual transport boxes for wafer batches, for example for 100 or 200 substrates. In a first variant, this can be a substantially rigid storage arrangement which is constructed in the manner of a conventional, fixed magazine installed in the transfer device 5. The individual compartments of the magazine are accessible for grasping by the grippers 14, 15, wherein the distance of the bearing sites of the compartments for wafers in the stack direction corresponds at least substantially to the distance of the individual grippers 15a of the stack gripper 15.

In another variant, the storage arrangement 24 can either have on its own or in addition to a magazine of the first variant, bearing elements which are movable relative to each other and are preferably able to be stacked directly one on another. Each of the bearing elements, which are not illustrated in further detail, can be provided with a bearing region to receive one wafer respectively. Such a storage arrangement and its means for opening and closing a stack from bearing elements at predeterminable locations in the stack is described in WO 2005006407 and PCT/CH2006/000356. The content of these publications is herewith explained by reference fully to the subject matter of this patent application.

In vertical direction beneath the storage arrangement, an arrangement 25 for the preparation of wafers is likewise provided inside the housing 6. In particular, this can be a marking/detection arrangement (notch finder), by which the detection of markings, such as notches for example, on the edge of the wafers is possible for determining their azimuthal position. Such so-called notch aligners detect the notch generally with an optical sensor, as is described for example in US 2002048506A1 and/or engage the notch or the wafer flat mechanically at a site when the wafer is rotated. The latter embodiment is described for example in US 0005662452A. Both methods are basically suitable to move the wafer subsequently into a defined angle position and can be provided for carrying out in the arrangement 25 of the transfer device 5 which is constructed as a functional unit. In other embodiments, the aligner can also be arranged directly on each gripper, as is described for example in WO 99/57752 and a corresponding product of the company RECIF, F-31840 Aussonne.

Between the storage arrangement 24 and the preparation arrangement 25, there is a feeding/discharge store 27 belonging to the lower feeding/discharge interface 26. This can have its own housing 28 with several storage spaces secured therein for a wafer or substrate respectively. In the example embodiment, for example, five storage spaces are provided. The feeding/discharge store 27 directly adjoins the site of the housing 6 of the transfer device 5, at which in the housing 6 a closable opening 29 (FIG. 3) of the second feeding/discharge interface 27 is provided for the exchange of wafers from the transfer device to the process station 4 or from the process station 4 to the transfer device 1.

The housing of the feeding/discharge store 27 has only one opening 31. The housing 28 of the feeding/discharge store 27 or else the entire feeding/discharge store 27 can be additionally in particular configured rotatably about a vertical axis. Hereby, in a first rotation position, access can be possible from the handling mechanism 12 onto the feeding/discharge store 27. In a second rotation position, shown in FIG. 3, the opening 31 can be turned to the process station 4 which—in relation to the feeding/discharge store—makes possible a feeding/discharge of wafers from or to the process station 4 directly adjoining the transfer device. In so far as the feeding/discharge store is provided with a housing 28, it is therefore possible in such a development to also manage with only one opening in its housing 28. The wafers inserted into the feeding/discharge store 27 by the process station 4 or by the handling mechanism 12, after a rotary movement of approximately 90° respectively after their insertion can be removed by the other respective functional unit (process station or handling mechanism).

In another embodiment of the feeding/discharge store, its housing is provided with a second opening 32, pointing towards the handling mechanism 12, through which also without a rotary movement wafers can be inserted into the feeding/discharge store 27 and removed, both from the process station and also from the handling mechanism 12. In addition, embodiments can also be provided, the feeding/discharge stores 27 of which manage without a housing.

In a preferred further development, the feeding/discharge store 27 can also be divided into two and can have two partial feeding/discharge stores which are independent of each other. Here, respectively one of the partial feeding/discharge stores can serve to receive wafers from the process station 4 and the other partial feeding/discharge store can serve for the preparation of wafers for a transfer to the process station.

To produce clean room conditions in the closable housing 6 of the transfer device, on one side of the housing a vertical duct 33 can be provided for the supply of clean air or nitrogen, which if applicable also flows through the transfer device 1 by means of flow-directing elements in a predetermined manner.

With the transfer device according to the invention, it is possible for the first time to introduce and receive wafers directly from an overhead conveying system without a transport box into a transfer device, to store them intermediately, open, under clean room conditions, and to transfer them directly, i.e. without an arrangement in a transport box, to a process station. In addition, it is also possible with the transfer device to convey wafers directly by the transfer device from one feeding/discharge interface 7, 26 to the other respective feeding/discharge interface 7, 26 situated in vertical direction at another location of the housing 6, in order to supply individual wafers or a stack of wafers without intermediate storage in the housing 6 from the overhead conveying system 1 to the process station 4 or vice versa.

Finally, an opened transport box arranged at the feeding/discharge interface 6, after a removal of (unprocessed) wafers 3, can also be loaded immediately with other (processed) wafers 3 again by the handling mechanism 12, without the transport box being removed from the interface 6 or closed in the meantime. For this, the handling mechanism 12 can deposit the introduced wafers at a designated location, for example in the storage arrangement 24, receive the other wafers thereafter and insert these into the transport box. The latter is then closed and is then ready to be transported off by the overhead conveying system. With such a sequence, particularly short dwell times of wafers can be achieved in the transfer device and the number of transport boxes which are to be transported when empty or intermediately stored when empty can be reduced. This advantage can be further increased in that a handling mechanism 12 is used which is capable of receiving two wafer stacks at the same time, and for this in particular has two stack grippers. The handling mechanism 12 can move here with a stack of processed wafers to the interface 7, remove a stack of (unprocessed) wafers there from the transport box and immediately thereafter insert the stack of (processed) wafers into the transport box. Only thereafter are the unprocessed wafers transferred by the handling mechanism to a suitable location of the transfer device. The same advantage as with wafer stacks can also be achieved in transport boxes with only one storage space, if the handling mechanism is provided with two single grippers.

Preferred embodiments of the invention have the advantage that with them in addition in such a transfer device, new wafer stacks can also be assembled with the aid of one and/or both grippers 14, 15. In addition, the wafers provided for discharge can be brought into a predetermined rotation position by means of the preparation arrangement 25. In an embodiment which is not shown in further detail, the preparation arrangement 25 of the transfer device can also have a particle detection arrangement, by which contamination of the substrates can be detected and removed if necessary.

### LIST OF REFERENCE NUMBERS

1 overhead conveying system
2 transport box
2a cover
3 wafer
4 process station
5 transfer device
6 housing
7 first feeding/discharge interface
7a charging position
8 transport box changer
9 platform
10 first position
12 handling mechanism
13 second position
14 single gripper
15 stack gripper
15a gripper of the stack gripper
16 slide carrier
20 three-point bearing
21 three-point bearing
22 three-point bearing
24 storage arrangement
25 preparation arrangement
26 lower feeding/discharge interface
27 feeding/discharge store
28 housing
29 closable opening
30 storage space
31 opening
32 opening
33 duct

1. A transfer device for substrates from the field of the manufacture of electronic components or displays, which is provided for the delivery of substrates to a process station, wherein the transfer device is provided with a housing which has a first feeding/discharge interface to an overhead conveying system for substrate transport boxes, and a second feeding/discharge interface to the process station, the first interface being arranged here, in relation to a vertical direction, above the second interface,
characterized
by means by which the substrates are able to be transported by a handling mechanism (12), arranged in the transfer device (5), free of transport boxes, from one interface (7, 26) to the other.

2. The transfer device according to claim 1, characterized by a handling mechanism (12) for the introduction, free of transport boxes and/or magazines, of substrates into the transfer device.

3. The transfer device according to one or both of the preceding claims, characterized by a storage arrangement (24), arranged in the transfer device, with storage spaces for the intermediate storage of substrates.

4. The transfer device according to claim 3, characterized by a storage arrangement (24), arranged inside the housing (6), which has storage elements which are able to be stacked on each other and are movable relative to each other, to receive a substrate respectively.

5. The transfer device according to at least one of the preceding claims, characterized by means for the assembly of a wafer stack inside the housing (6).

6. The transfer device according to at least one of the preceding claims, characterized by means for the detection of the azimuthal position of substrates and by means for altering the azimuthal position.

7. The transfer device according to at least one of the preceding claims, characterized in that wafers are able to be prepared for transfer to a process station by the handling mechanism (12) arranged in the transfer device.

8. The transfer device according to at least one of the preceding claims, characterized by a handling mechanism (12) which has both a stack gripper (15) and also at least one single gripper (14).

9. The transfer device according to at least one of the preceding claims, characterized by a feeding/discharge store (27) as a component of the second feeding/discharge interface (26), in which substrates are able to be deposited and removed for an exchange with the process station.

10. The transfer device according to claim 9, characterized by movement means of the feeding/discharge store (27), in particular movement means for producing a rotary movement.

11. The transfer device according to at least one of the preceding claims, characterized by a transport box changer (8), by which transport boxes arranged in front of or on a housing (6) of the transfer device are able to be transferred from a loading position (10) to a buffer position (13) and vice versa.

12. The transfer device according to at least one of the preceding claims, characterized by means for the production of clean room conditions inside the housing (6) of the transfer device.

13. A method for the delivery of at least one substrate to a process station, wherein the at least one substrate arranged in a transport box is provided from an overhead conveying system (1) at a first feeding/discharge interface (7) of a transfer device (5) arranged in front of a process station (4), characterized in that the at least one substrate is removed from the transport box in the region of the first feeding/discharge interface (7), is introduced without the transport box into a housing of the transfer device, and is subsequently transferred to a second feeding/discharge interface of the transfer arrangement and is provided there for the process station.

14. The method according to claim 13, characterized in that substrates are intermediately stored, open, inside a housing of the transfer device.

15. The method according to at least one of the preceding claim 11 or 12, characterized in that in the transfer device an alignment of substrates takes place into a rotation target position.

16. The method according to at least one of the preceding claims 11 to 13, characterized in that inside the housing of the transfer device at least one substrate is arranged into a feeding/discharge store of the second feeding/discharge interface.
